(19) United States
(12) Patent Application Publication
(10) Pub. No.: US 2019/0019730 A1
(43) Pub. Date: Jan. 17, 2019

(54) EFFECTIVE COMPOUND SUBSTRATE FOR NON-DESTRUCTIVE EPITAXIAL LIFT-OFF

(71) Applicant: The Regents of the Univeristy of Michigan, ANN ARBOR, MI (US)

(72) Inventors: Stephen R. Forrest, Ann Arbor, MI (US); Kyusang Lee, Ann Arbor, MI (US)

(21) Appl. No.: 16/076,805

(22) PCT Filed: Feb. 24, 2017
(86) PCT No.: PCT/US2017/019331

§ 371 Date: Aug. 9, 2018

Related U.S. Application Data
(60) Provisional application No. 62/299,058, filed on Feb. 24, 2016.

(51) Int. Cl. H01L 21/78; H01L 21/02; H01L 21/304; B32B 43/00

(52) U.S. Cl. CPC H01L 21/7813; H01L 21/02546; H01L 33/0079; H01L 21/304; B32B 43/006; H01L 21/02381

(57) ABSTRACT

The present disclosure relates to compound substrates for use in epitaxial lift-off. In one implementation, a compound substrate may include a diced wafer layer formed of a plurality of wafer pieces and a wafer-receiving layer having a surface. The wafer layer may have a bottom surface and a top surface, and the bottom surface of the wafer layer may be attached to the surface of the wafer-receiving layer.

### CROSS-REFERENCE TO RELATED APPLICATION

This application claims the benefit of priority to U.S. Provisional Patent Application No. 62/299,058, filed on Feb. 24, 2016, which is incorporated by reference herein in its entirety.

### STATEMENT REGARDING FEDERALLY SPONSORED RESEARCH

This invention was made with government support under W911NF-08-2-0004 awarded by the U.S. Army/Army Research Office. The government has certain rights in the invention.

### JOINT RESEARCH AGREEMENT

The subject matter of this application was made by, on behalf of, and/or in connection with one or more of the following parties to a joint university-corporation research agreement: The Regents of the University of Michigan and NanoFlex Power Corporation. The agreement was in effect on and before the date the subject matter of this application was made, and such was made as a result of activities undertaken within the scope of the agreement.

The present disclosure generally relates to substrates for use in epitaxial lift-off. More particularly, and without limitation, the present disclosure relates to compound substrates for use in non-destructive epitaxial lift-off.

Epitaxial lift-off is frequently used to separate the active device region from the wafer on which it is deposited. Generally, epitaxial lift-off is performed by selectively etching the sacrificial layer located between the active device region and the wafer. Epitaxial lift-off may permit re-use of the wafer following separation of the active device region.

However, conventional epitaxial lift-off techniques generally result in roughening of the wafer surface, accumulation of contaminants thereon, and/or even breaks in the wafer. One solution is to prepare the wafer for re-use by using post-lift-off chemo-mechanical polishing to reduce roughening and eliminate contaminants. However, such polishing reduces the thickness of the wafer and inflicts additional damage on the wafer, generally limiting the wafer's possible re-use to a few growth and polishing cycles.

Therefore, there is a need for recyclable materials and/or recycling techniques that preserve the wafer quality between growth and polishing cycles and allow for efficient repair of damaged wafers. The present disclosure meets these needs.

The disclosed embodiments include compound substrates for use in epitaxial lift-off of a device. Advantageously, this may permit recycling of wafers even with critical defect accumulation or after partial breakage. Furthermore, compound substrates may have a greater re-use life as compared to conventional substrates. Such substrates may have uses in conventional epitaxial lift-off methods, non-destructive epitaxial lift-off methods, etc.

In one embodiment, a compound substrate for use in epitaxial lift-off of a device having an expected size comprises a diced wafer layer formed of a plurality of wafer pieces, wherein the wafer layer has a bottom surface and a top surface; and a wafer-receiving layer having a surface, wherein the bottom surface of the wafer layer is attached to the surface of the wafer-receiving layer.

In another embodiment, a method of manufacturing a compound substrate for use in epitaxial lift-off of a device having an expected size comprises providing a wafer layer, wherein the wafer has a bottom surface and a top surface; dicing the wafer layer into a plurality of pieces; and attaching the bottom surface of the diced wafer layer to a wafer-receiving layer.

In another embodiment, a method of manufacturing a device having an expected size using epitaxial lift-off comprises providing a wafer layer, wherein the wafer has a bottom surface and a top surface; dicing the wafer layer into a plurality of pieces; attaching the bottom surface of the diced wafer layer to a wafer-receiving layer; bonding a host substrate atop the wafer layer; and releasing the host substrate from the wafer layer by etching.

In another embodiment, a method of repairing a compound substrate having a plurality of wafer pieces and damage in a localized area comprises: selectively heating the localized area; removing the one or more pieces in the localized area, thereby forming one or more empty areas; and bonding one or more new pieces of wafer to fill the one or more empty areas.

In one embodiment of the present disclosure, the disclosed compound substrate includes a diced wafer layer. The diced wafer layer may be formed of a plurality of wafer pieces and may have a bottom surface and a top surface. In some embodiments, the size of each piece of the wafer layer may be smaller than the expected size of the device. In other embodiments, the size of each piece of the wafer layer may be larger than the expected size of the device. In some embodiments, the wafer pieces may be of uniform size. Advantageously, the pieces of the wafer layer may be selectively replaced if degraded or broken, thereby easing recycling of the wafer and lowering material costs. Moreover, broken pieces may be salvaged and re-used to create new wafer layers, such as by dicing the broken wafer pieces, further lowering material costs.

In some embodiments, the wafer layer may include at least one III-V semiconductor. In certain aspects, the at least one III-V semiconductor may include GaAs.

The compound substrate further includes a wafer-receiving layer having a surface. The bottom surface of the wafer layer may be attached to the surface of the wafer-receiving layer. In some embodiments, the wafer-receiving layer may include at least one semiconductor. In certain aspects, the wafer-receiving layer may include silicon. In some embodiments, the wafer-receiving layer may include one or more crystalline solids. In certain aspects, the wafer-receiving layer may include quartz.

In some embodiments, the compound substrate may further include an active device region. In epitaxial lift off, the active device region is a region lifted off of the effective compound substrate for use as or in a desired device. The active device region may be disposed on the wafer layer.

In some embodiments, the compound substrate may further include one or more sacrificial layers. The one or more sacrificial layers may be disposed between the wafer layer and the active device region. In some embodiments, the one or more sacrificial layers may include at least one III-V semiconductor. In certain aspects, the at least one III-V semiconductor may include AlAs. In epitaxial lift off, the one or more sacrificial layers are removed thereby lifting off the active device region from the effective compound substrate.

In some embodiments, the compound substrate may further include one or more protection layers. The one or more protection layers may be disposed between the wafer layer and the active device region. In some embodiments, the one or more protection layers may include at least one III-V semiconductor. In certain aspects, the at least one III-V semiconductor may include at least one of GaAs or InGaP. U.S. Pat. No. 8,378,385 and U.S. Patent Publication No. 2013/0043214 are hereby incorporated by reference for their disclosure of layers and materials for epitaxial lift off, and in particular for their disclosure of protection layers.

In some embodiments, the compound substrate may further include a host substrate. The host substrate may be bonded to the active device region. In some embodiments, the host substrate may include a Kapton sheet. In certain aspects, the host substrate may further include an adhesion layer. In certain aspects, the adhesion layer may include iridium.

In some embodiments, the compound substrate may further include one or more metal layers. The metal layers may be disposed between the active device region and the host substrate. In certain aspects, the one or more layers may include at least one of palladium, germanium, or gold.

In other embodiments, the compound substrate may further include a handle layer. The handle layer may be attached to the active device region. In some embodiments, the handle layer may be attached to the active device region, at least in part, with one or more adhesives.

The disclosed embodiments further include a method of manufacturing a compound substrate for use in epitaxial lift-off of a device having an expected size. The method includes providing a wafer layer. The wafer layer may have a bottom surface and a top surface.

In some embodiments, providing a wafer layer may further include depositing one or more sacrificial layers on the wafer layer. In some embodiments, providing a wafer layer may further include depositing an active device region on the wafer layer, wherein the active device region is disposed over the one or more sacrificial layers. In some embodiments, providing a wafer layer may further include depositing one or more protection layers on the wafer layer, wherein the one or more protection layers are disposed between the wafer layer and the one or more sacrificial layers.

In some embodiments, providing a wafer layer may further include depositing a host substrate or a handle on the wafer layer, wherein the host substrate or handle is disposed over the active device region, for example is bonded to the active device region. In some embodiments, bonding the host substrate may include at least one of direct wafer bonding, indium bonding, cold-welding, or thermocompression bonding. Other appropriate bonding methods may be used, and bonding methods may be used in any appropriate combination. In certain aspects, the method may further include depositing an adhesion layer on the host substrate. In some embodiments, the handle is attached to the active device region and may be attached, for example, at least in part, with one or more adhesives.

The method may further include depositing one or more metal layers on the host substrate. The metal layers may be disposed between the active device region and the host substrate. In certain aspects, the one or more metal layers include at least one of palladium, germanium, or gold. In some embodiments, depositing one or more metal layers on the host substrate may include, at least in part, depositing using e-beam evaporation.

In some embodiments, the wafer layer may be diced before disposing additional layers (e.g., one or more sacrificial layers, active device region, protection layers, etc.) on top. In other embodiments, the wafer layer is diced after depositing any number of additional layers on top (e.g., the sacrificial layer, active device region, protection layers, etc.). For example, in some embodiments, one or more sacrificial layers, an active device region, optional one or more protective layers, optional one or more buffer layers, and a host substrate are disposed on the wafer layer before dicing. In some embodiments where additional layers are disposed over the wafer layer before the wafer layer is diced, the additional layers may be cut in addition to the wafer layer during dicing. In other embodiments where additional layers are disposed over the wafer layer before the wafer layer is diced, only the wafer layer may be cut during dicing.

In some embodiments, the size of each piece of the wafer layer may be smaller than the expected size of the device. In other embodiments, the size of each piece of the wafer layer may be larger than the expected size of the device. In some embodiments, the pieces of the wafer layer may be of uniform size.

In some embodiments, the method may further include attaching the bottom surface of the diced wafer layer to a wafer-receiving layer. In some embodiments, attaching the bottom surface of the wafer layer to a wafer-receiving layer may include at least one of direct wafer bonding, indium bonding, cold-welding, or using silicon on glass (SOG). Other appropriate bonding methods may be used, and bonding methods may be used in any appropriate combination. In some embodiments, attaching the diced wafer layer to a wafer-receiving layer may include, at least in part, attaching with one or more adhesives.

The disclosed embodiments further include a method of manufacturing a device having an expected size using epitaxial lift-off. The method may include providing a wafer layer. The wafer layer may have a bottom surface and a top surface. In some embodiments, providing a wafer layer may further include depositing one or more sacrificial layers on the wafer layer. In some embodiments, providing a wafer layer may further include depositing an active device region, wherein the active device region is disposed over the one or more sacrificial layers. In some embodiments, providing a wafer layer may further include depositing one or more protection layers on the wafer layer, wherein the one or more protection layers are disposed between the wafer layer and the one or more sacrificial layers.

The method may further include bonding a host substrate atop the wafer layer. In some embodiments, bonding the host substrate may include at least one of direct wafer bonding, indium bonding, or thermocompression bonding. Other appropriate bonding methods may be used, and bonding methods may be used in any appropriate combination. In other embodiments, bonding the host substrate to the active device region may include depositing one or more metal layers on the host substrate and bonding the host substrate, at least in part, using cold-welding. In certain aspects, depositing one or more metal layers on the host substrate may include, at least in part, depositing using e-beam evaporation.

The method may further include dicing the wafer layer into a plurality of wafer pieces. As described above, the wafer layer may be diced before or after disposing any number of additional layers (e.g., one or more sacrificial layers, active device region, protection layers, host substrate, etc.) on top. In some embodiments, the size of each piece of the wafer layer may be smaller than the expected size of the device. In other embodiments, the size of each piece of the wafer layer may be larger than the expected size of the device. In some embodiments, the pieces of the wafer layer may be of uniform size.

The method may further include attaching the bottom surface of the diced wafer layer to a wafer-receiving layer. In some embodiments, attaching bottom surface of the wafer layer to a wafer-receiving layer may include at least one of direct wafer bonding, indium bonding, cold-welding, or using silicon on glass (SOG). Other appropriate bonding methods may be used, and bonding methods may be used in any appropriate combination. In some embodiments, attaching the diced wafer layer to a wafer-receiving layer may include, at least in part, attaching with one or more adhesives.

The method may further include releasing the host substrate from the wafer layer. The host substrate may be released, thereby lifting off the active device region from the effective compound substrate, by selectively removing the one or more sacrificial layers. In some embodiments, the one or more sacrificial layers are removed by etching. In some embodiments, releasing the active device region and host substrate may include submerging the wafer layer in an acid, for example, dilute hydrofluoric acid, thereby etching the one or more sacrificial layers. In certain aspects, the wafer layer may be submerged between two and twenty-four hours. The duration of the submerging may depend on the size of the wafer layer and/or the size of the host substrate.

In some embodiments, the method may further include selectively removing the one or more protection layers. In certain aspects, selectively removing the one or more protection layers may include etching the one or more protection layers, such as etching using a phosphoric acid-based etchant and/or etching using diluted HCl acid.

The disclosed embodiments may further include a method of repairing a compound substrate comprising a wafer-receiving layer and a plurality of wafer pieces bonded to the wafer-receiving layer having damage in a localized area. The method may include selectively heating the localized area. The method may further include removing the one or more pieces in the localized area, thereby forming one or more empty areas. The method may further include bonding one or more new pieces of wafer to the wafer-receiving layer to fill the one or more empty areas.

In some embodiments, bonding one or more new pieces of wafer may include at least one of direct wafer bonding, indium bonding, cold-welding, using silicon on glass (SOG), or thermocompression bonding. Other appropriate bonding methods may be used, and bonding methods may be used in any appropriate combination.

In some embodiments, the disclosed methods for manufacturing a compound substrate for use in growth of a device having an expected size or for repairing a compound substrate having a host substrate, a plurality of wafer pieces, and damage in a localized area may be combined with known methods for non-destructive epitaxial lift-off. PCT/US2015/011601 is incorporated herein by reference for its disclosure of a non-destructive epitaxial lift-off process. In other embodiments, the disclosed methods may be combined with known methods for convention epitaxial lift-off.

### BRIEF DESCRIPTION OF FIGURES

FIGS. 1A, 1B, and 1C. FIG. 1A shows a diagram of the layers comprising an exemplary effective compound substrate, according to embodiments of the present disclosure. FIG. 1B shows a cross-sectional view of the exemplary compound substrate of FIG. 1A, according to embodiments of the present disclosure. FIG. 1C shows an alternate cross-sectional view of the exemplary compound substrate of FIG. 1A, according to embodiments of the present disclosure.

FIG. 2. A flowchart depicting an exemplary method of manufacturing a compound substrate for use in epitaxial lift-off of a device having an expected size, according to embodiments of the present disclosure, is shown.

FIGS. 3A and 3B. FIG. 3A shows a flowchart depicting an exemplary method of repairing a compound substrate having a plurality of wafer pieces and damage in a localized area, according to embodiments of the present disclosure. FIG. 3B shows a pictorial representation of the exemplary method of FIG. 3A, according to embodiments of the present disclosure.

FIG. 4. A flowchart depicting an exemplary method of manufacturing a device having an expected size using epitaxial lift-off, according to embodiments of the present disclosure, is shown.

### DETAILED DESCRIPTION

As used herein, the term “layer” refers to a member or component of a photosensitive device whose primary dimension is X-Y, i.e., along its length and width, and is typically perpendicular to the plane of incidence of the illumination. It should be understood that the term “layer” is not necessarily limited to single layers or sheets of materials. A layer may comprise laminates or combinations of several sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) and/or material(s).

As used herein, the expression “disposed on,” “located over,” and the like permits other materials or layers to exist between a material being disposed and the material on or over which it is disposed. Likewise, the expression “bonded to” permits other materials or layers to exist between a material being bonded and the material to which it is bonded.

As used herein, the term “diced” refers to a subdivision of a whole component into a plurality of pieces. Accordingly, it should be understood that the term “diced” refers to all forms of cutting or otherwise separating a component into one or more pieces and is not necessarily limited to division into pieces that comprise squares or other shapes of equal size. For example, a component may be “diced” into pieces with each piece having a different shape.

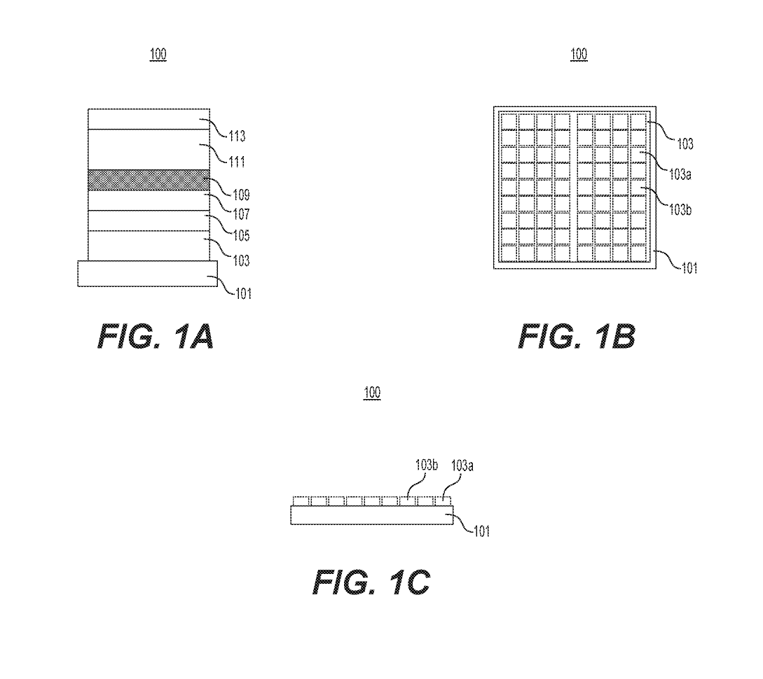

In one embodiment of the present disclosure, a compound substrate for use in epitaxial lift-off of a device having an expected size is disclosed (FIG. 1A). However, even though the compound substrate is adapted for use with epitaxial list-off techniques, additional uses of the disclosed embodiments are possible.

As depicted in FIG. 1A, the compound substrate 100 may include a wafer-receiving layer 101. Wafer-receiving layer 101 may comprise one or more materials suitable to receive a diced wafer on its surface, for example, by providing sufficient structural integrity for receiving the diced wafer. In some embodiments, wafer-receiving layer 101 may include one or more semiconductors. For example, wafer-receiving layer 101 may include silicon. In some embodiments, wafer-receiving layer 101 may include one or more crystalline solids. For example, wafer-receiving layer 101 may include quartz.

As further depicted in FIG. 1A, compound substrate 100 may include a wafer layer 103. In certain aspects, wafer layer 103 may include one or more semiconductors. For example, wafer layer 103 may include silicon. In other aspects, wafer layer 103 may include one or more semiconductor compounds. For example, wafer layer 103 may include a III-V semiconductor, e.g., GaAs. In certain aspects, wafer layer 103 may have a thickness between 350 μm and 500 μm.

As depicted in FIG. 1A, wafer layer 103 may be attached to wafer-receiving layer 101. For example, wafer layer 103 may be attached to wafer-receiving layer 101 with one or more adhesives, e.g., thermal releasing tape, kapton tape, wax, or glue. In other embodiments, wafer layer 103 may be bonded to wafer-receiving layer 101. For example, wafer layer 103 and wafer-receiving layer 101 may be directly bonded using direct wafer bonding, indium bonding, cold-welding, using silicon on glass (SOG), etc., or any combination thereof. In certain aspects, cold-welding may, for example, be performed at high vacuum pressure, e.g., no greater than 10⁻³ Torr, with an applied force between 2 MPa and 20 MPa, and at a temperature between 100° C. and 250° C.

As depicted in FIG. 1B, wafer layer 103 of compound substrate 100 may be diced into a plurality of pieces, e.g., piece 103a and piece 103b. The number of pieces comprising diced wafer layer 103 may be varied and the pieces may be arranged in any desired shape. In some embodiments, each piece may have a size smaller than the expected size of the device. In other embodiments, each piece may have a size larger than the expected size of the device. In certain aspects, the pieces may be of uniform size—that is, each piece may have the same size as the other piece(s). FIG. 1C shows an alternate cross-sectional view of piece 103a, piece 103b, and wafer-receiving layer 101 of compound substrate 100 depicted in FIGS. 1A and 1B.

Returning to FIG. 1A, compound substrate 100 may further include one or more buffers layers, e.g., buffer layer 105. In some embodiments, buffer layer 105 may be diced along with wafer layer 103. In other embodiments, buffer layer 105 may not be diced. In certain aspects, buffer layer 105 may include at least one semiconductor. For example, buffer layer 105 may include a III-V semiconductor, e.g., GaAs or InGaP. In certain aspects, buffer layer 105 may have a thickness between 50 nm and 500 nm.

As further depicted in FIG. 1A, compound substrate 100 may further include one or more (epitaxial) protection layers, e.g., protection layer 107. In some embodiments, protection layer 107 may be diced along with wafer layer 103. In other embodiments, protection layer 107 may not be diced. In certain aspects, protection layer 107 may include at least one semiconductor. For example, protection layer 107 may include a III-V semiconductor, e.g., GaAs or InGaP. In certain aspects, protection layer 107 may have a thickness between 50 nm and 1000 nm. In certain aspects, compound substrate 100 may include additional buffer layers and/or protection layers. Additional buffer layers, protection layers, and combined buffer/protection layers may also be diced along with wafer layer 103. In other embodiments, they may not be diced.

As further depicted in FIG. 1A, compound substrate 100 may further include one or more sacrificial layers, e.g., sacrificial layer 109. In some embodiments, sacrificial layer 109 may be diced along with wafer layer 103. In other embodiments, sacrificial layer 109 may not be diced. Sacrificial layer 109 may be adapted to be removed during epitaxial lift-off. For example, sacrificial layer 109 may be adapted for dissolution in dilute hydrofluoric acid (HF). In certain aspects, sacrificial layer 109 may include at least one semiconductor. For example, sacrificial layer 109 may include a III-V semiconductor, e.g., AlAs.

As further depicted in FIG. 1A, an active device region 111 may be deposited on sacrificial layer 109. In some embodiments, active device region 111 may be diced along with wafer layer 103. In other embodiments, active device region 111 may not be diced. Active device region 111 may include one or more photovoltaic cells, one or more light emitted diodes (LEDs), one or more field effect transistors (FETs), or one or more other devices appropriate for deposition on a substrate. Active device region 111 may detach from compound substrate 100 upon dissolution of sacrificial layer 109, e.g., during immersion in dilute hydrofluoric acid (HF).

Compound substrate 100 may include a handle layer (not shown) attached to active device region 111. In some embodiments, the handle may be diced along with wafer layer 103. In other embodiments, the handle may not be diced. In some embodiments, the handle layer may include at least one plastic. In certain aspects, the handle layer may include thermal release tape, polyimide coating, etc., or any combination thereof. In some embodiments, the handle layer may include at least one metal. In some embodiments, the handle layer may include wax.

In some embodiments, the handle layer may be attached to active device region 111 with one or more adhesives, e.g., thermal releasing tape, kapton tape, wax, or glue.

As depicted in FIG. 1A, compound substrate 100 may further include a host substrate 113 attached to active device region 111. In some embodiments, host substrate 113 is diced along with wafer layer 103. In other embodiments, host substrate 113 may not be diced. In some embodiments, host substrate 113 may include a Kapton sheet. In certain aspects, host substrate 113 may further include an adhesion layer. For example, the adhesion layer may include iridium. In some embodiments, host substrate 113 may have a thickness between 25 μm and 125 μm. In some embodiments, host substrate 113 may be bonded to active device region 111 using direct wafer bonding, indium bonding, cold-welding, thermocompression bonding, etc., or any combination thereof. In certain aspects, cold-welding may, for example, be performed at high vacuum pressure, e.g., no greater than 10⁻³ Torr, with an applied force between 2 MPa and 20 MPa, and at a temperature between 100° C. and 250° C.

In some embodiments, compound substrate 100 may further include one or more metal layers (not shown). The metal layers may be disposed between active device region 111 and host substrate 113. In certain aspects, the one or more layers may include, for example, palladium, germanium, and/or gold. For example, compound substrate 100 may include one or more alternating patterns of metal layers, e.g., a first palladium layer, followed by a germanium layer, followed by a first gold layer, followed by a second palladium layer, followed by a second gold layer. The thickness of each layer in the one or more metal layers may vary. For example, the thickness of the first palladium layer may be 5 nm, the thickness of the germanium layer may be 25 nm, the thickness of the first gold layer may be 65 nm, the thickness of the second palladium layer may be 5 nm, and the thickness of the second gold layer may be between 100 nm and 1 μm. In some embodiments, the one or more metal layers may be deposited using e-beam evaporation. Advantageously, the one or more metal layers may permit for cold-welding of host substrate 113 to active device region 111.

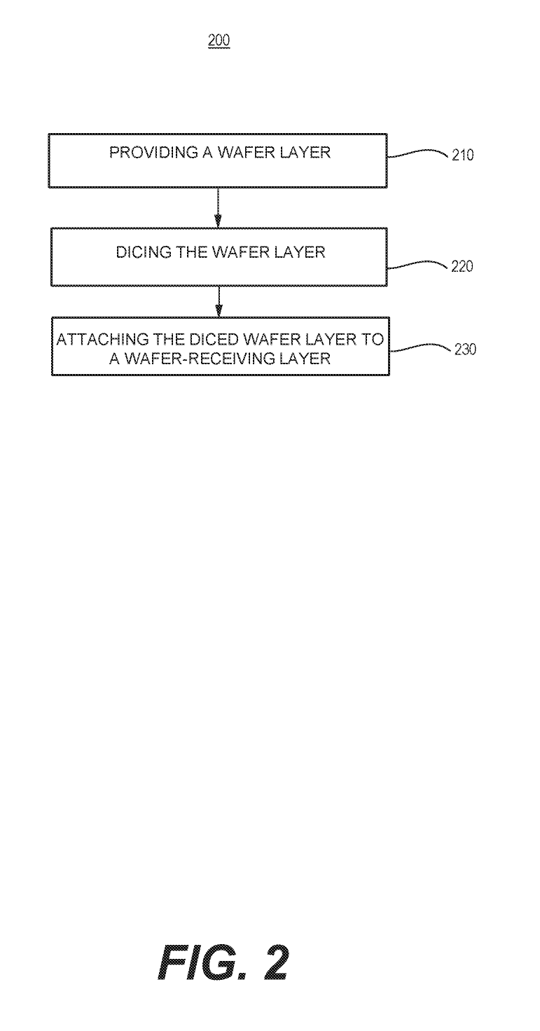

Another aspect of the present disclosure is directed to a method of manufacturing a compound substrate for use in growth of a device having an expected size (FIG. 2). The method 200 may include step 210, providing a wafer layer. For example, the wafer layer may have a bottom surface and a top surface. By way of further example, the wafer layer may include at least one III-V semiconductor. For example, the at least one III-V semiconductor may include GaAs.

In some embodiments, step 210 of method 200 may further include depositing one or more sacrificial layers on the wafer layer. For example, the one or more sacrificial layers may be adapted to be removed during epitaxial lift-off. For example, the one or more sacrificial layers may be adapted for dissolution in dilute hydrofluoric acid (HF). By way of further example, the one or more sacrificial layers may include one or more semiconductors. For example, the one or more sacrificial layers may include one or more III-V semiconductors, e.g., AlAs.

In some embodiments, step 210 of method 200 may further include depositing an active device region as described herein on the wafer layer, wherein the active device region is disposed over the one or more sacrificial layers.

In some embodiments, step 210 of method 200 may further include depositing one or more protection layers on the wafer layer, wherein the one or more protection layers are disposed between the wafer layer and the one or more sacrificial layers. For example, the one or more protection layers may include at least one semiconductor. By way of further example, the one or more protection layers may include one or more III-V semiconductors, e.g., GaAs or InGaP.

The example method 200 may include additional steps not depicted in FIG. 2. For example, method 200 may further include bonding a host substrate to the active device region. For example, the host substrate may comprise a Kapton sheet.

In some embodiments, bonding the host substrate may include at least one of direct wafer bonding, indium bonding, cold-welding, or thermocompression bonding. Of course, other appropriate bonding methods may be used, and bonding methods may be used in any appropriate combination. In some embodiments, bonding the host substrate may further include depositing an adhesion layer on the host substrate. For example, the adhesion layer may include iridium.

By way of additional example, method 200 may further include depositing one or more metal layers on the host substrate. For example, the one or more metal layers may be disposed between the active device region and the host substrate. By way of further example, the one or more metal layers include at least one of palladium, germanium, or gold. In some embodiments, depositing one or more metal layers on the host substrate may include, at least in part, depositing using e-beam evaporation.

By way of additional example, method 200 may further include attaching a handle layer to an active device region located on the one or more sacrificial layers. For example, a handle layer may include at least one plastic. Examples of materials including at least one plastic may include thermal release tape, polyimide coating, or any combination thereof. By way of further example, a handle layer may include at least one metal. By way of further example, a handle layer may include wax. In some embodiments, attaching the handle layer to the active device region may include, at least in part, attaching with one or more adhesives, e.g., thermal releasing tape, kapton tax, wax, or glue.

As further depicted in FIG. 2, method 200 includes step 220, dicing the wafer layer. For example, the wafer layer may be diced into a plurality of pieces. As described above, the wafer layer may be diced into a plurality of pieces before or after disposing any number of additional layers (e.g., one or more sacrificial layers, active device region, protection layers, host substrate, etc.) on top. In some embodiments, the size of each piece of the wafer layer may be smaller than the expected size of the device. In other embodiments, the size of each piece of the wafer layer may be larger than the expected size of the device. In some embodiments, the wafer layer may be diced uniformly—that is, into a plurality of pieces such that each piece has the same size as the other piece(s).

As depicted in FIG. 2, method 200 further includes step 230, attaching the bottom surface of the diced wafer layer to a wafer-receiving layer. For example, the wafer-receiving layer may include one or more semiconductors, e.g., silicon. By way of further example, the wafer-receiving layer may include one or more crystalline solids, e.g., quartz.

In some embodiments, step 230 of method 200 may include at least one of direct wafer bonding, indium bonding, cold-welding, or using silicon on glass (SOG). Of course, step 230 may include other appropriate bonding methods and may include any appropriate combination of bonding methods. In other embodiments, step 230 of method 200 may include, at least in part, attaching with one or more adhesives.

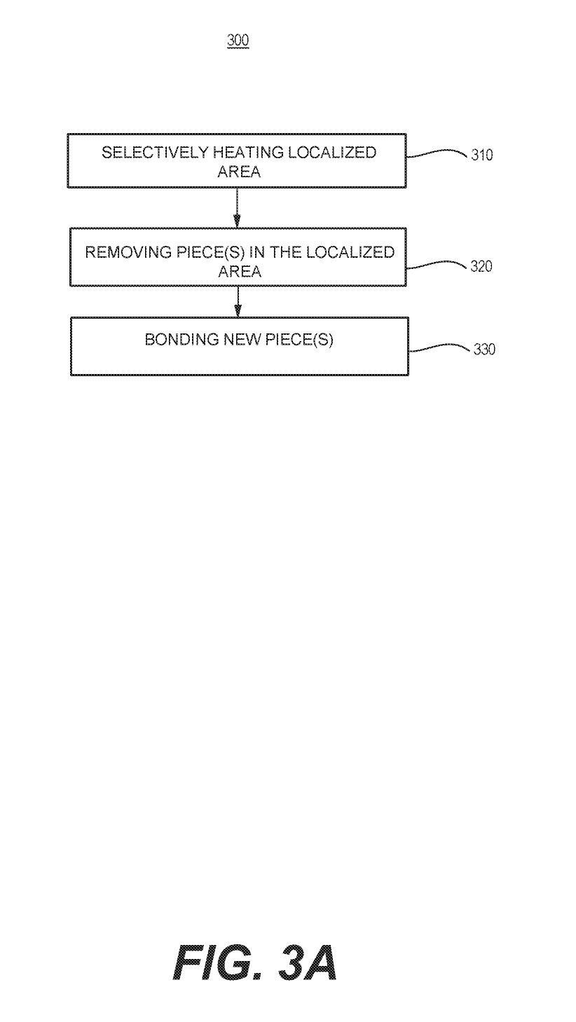

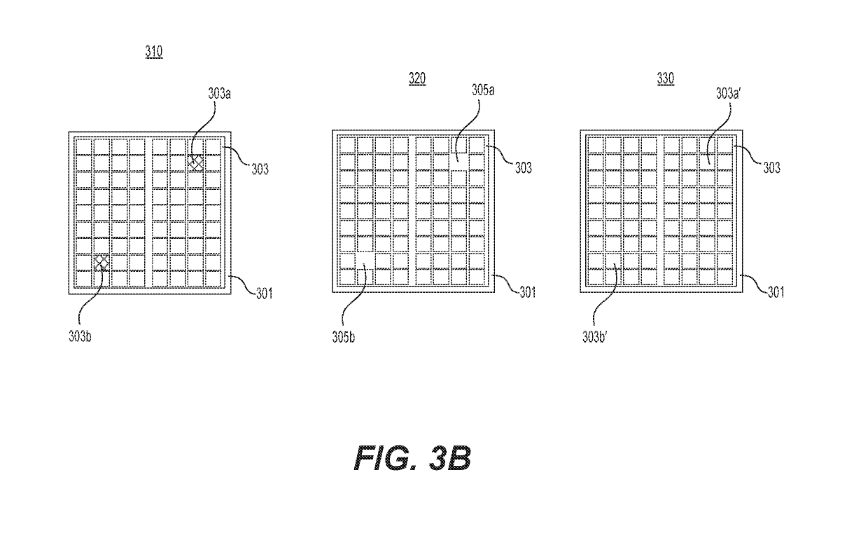

Another aspect of the present disclosure is directed to a method of repairing a compound substrate comprising a wafer-receiving layer and a plurality of wafer pieces bonded or attached to the wafer-receiving layer having damage in a localized area (FIG. 3A). The method 300 includes step 310, selectively heating the localized area. Advantageously, the selectively heating may cause the one or more pieces in the damaged area to become loosened.

As depicted in FIG. 3A, method 300 further includes step 320, removing the one or more pieces in the localized area. For example, this may result in the formation of one or more empty areas where the now-removed piece(s) were located.

As further depicted in FIG. 3A, method 300 includes step 330, bonding one or more new pieces of wafer to the wafer-receiving layer to fill the one or more empty areas. In certain aspects, bonding the one or more new pieces may include bonding using direct wafer bonding, indium bonding, cold-welding, using silicon on glass (SOG), thermocompression bonding, etc., or any combination thereof. In certain aspects, cold-welding may, for example, be performed at high vacuum pressure, e.g., no greater than 10⁻³ Torr, with an applied force between 2 MPa and 20 MPa, and at a temperature between 100° C. and 250° C.

Moreover, an example of method 300 is depicted in FIG. 3B. In particular, FIG. 3B depicts a compound substrate having wafer-receiving layer 301 and wafer layer 303 including a plurality of pieces. As depicted in FIG. 3B, piece 303a and piece 303b contain damage, and in step 310, piece 303a and piece 303b are selectively heated.

As further depicted in FIG. 3B, in step 320, piece 303a and piece 303b are removed, leaving empty area 305a and empty area 305b. FIG. 3B also depicts step 330, in which new piece 303a′ and new piece 303b′ are bonded to wafer layer 303, thereby filling empty area 305a and empty area 305b, respectively.

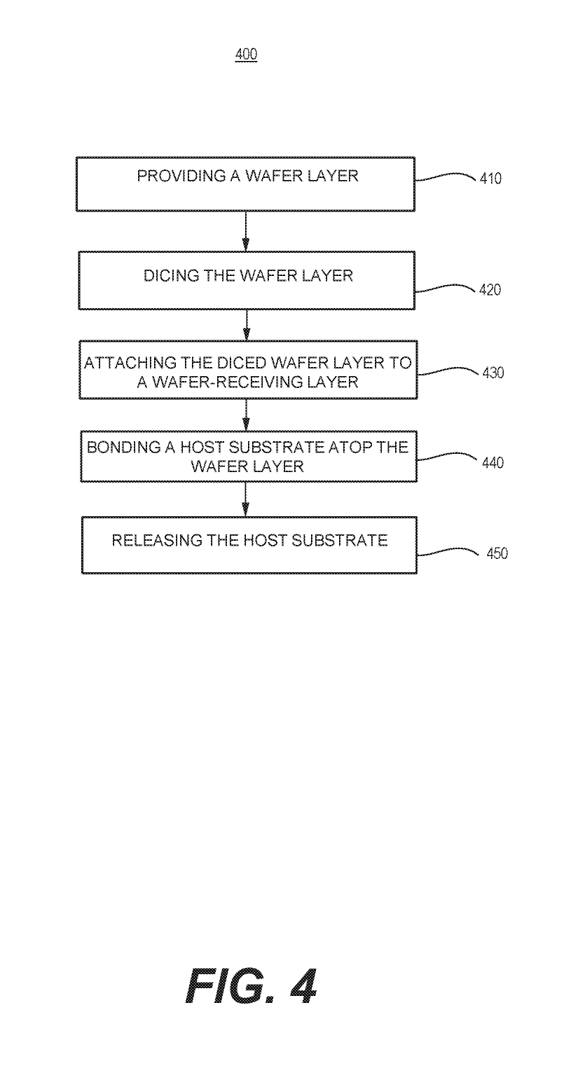

Another aspect of the present disclosure is directed to a method of manufacturing a device having an expected size using epitaxial lift-off (FIG. 4). The method 400 may include step 210, providing a wafer layer. For example, the wafer layer may have a bottom surface and a top surface. By way of further example, the wafer layer may include at least one III-V semiconductor. For example, the at least one III-V semiconductor may include GaAs.

In some embodiments, step 410 of method 400 may further include depositing one or more sacrificial layers on the wafer layer. For example, the one or more sacrificial layers may be adapted to be removed during epitaxial lift-off. For example, the one or more sacrificial layers may be adapted for dissolution in dilute hydrofluoric acid (HF). By way of further example, the one or more sacrificial layers may include one or more semiconductors. For example, the one or more sacrificial layers may include one or more III-V semiconductors, e.g., AlAs.

In some embodiments, step 410 of method 400 may further include depositing an active device region as described herein on the wafer layer, wherein the active device region is disposed over the one or more sacrificial layers.

In some embodiments, step 410 of method 400 may further include depositing one or more protection layers on the wafer layer, wherein the one or more protection layers are disposed between the wafer layer and the one or more sacrificial layers. For example, the one or more protection layers may include at least one semiconductor. By way of further example, the one or more protection layers may include one or more III-V semiconductors, e.g., GaAs or InGaP.

In some embodiments step 410 further includes bonding or attaching a host substrate or handle atop the wafer layer, such as bonding or attaching a host substrate or handle to the active device region. In these embodiments, step 440 in FIG. 4 is skipped, as the host substrate or handle is already bonded or attached atop the wafer layer.

As further depicted in FIG. 4, method 400 furthers include step 420, dicing the wafer layer. As described above, the wafer layer may be diced into a plurality of pieces before or after disposing any number of additional layers (e.g., one or more sacrificial layers, active device region, protection layers, host substrate, etc.) on top. The wafer layer may be diced, e.g., into a plurality of pieces. In some embodiments, the size of each piece of the wafer layer may be smaller than the expected size of the device. In other embodiments, the size of each piece of the wafer layer may be larger than the expected size of the device. In some embodiments, the wafer layer may be diced uniformly—that is, into a plurality of pieces such that each piece has the same size as the other piece(s).

As further depicted in FIG. 4, method 400 further includes step 430, attaching the bottom surface of the diced wafer layer to a wafer-receiving layer. For example, the wafer-receiving layer may include one or more semiconductors, e.g., silicon. By way of further example, the wafer-receiving layer may include one or more crystalline solids, e.g., quartz.

In some embodiments, step 430 of method 400 may include at least one of direct wafer bonding, indium bonding, cold-welding, or using silicon on glass (SOG). Of course, step 430 may include other appropriate bonding methods and may include any appropriate combination of bonding methods. In other embodiments, step 430 of method 400 may include, at least in part, attaching with one or more adhesives.

As depicted in FIG. 4, if a host substrate or handle has not been bonded or attached atop the wafer layer, e.g., bonded or attached to the active device region, then method 400 may further include step 440, bonding a host substrate atop the wafer layer. For example, the host substrate may include a Kapton sheet. By way of further example, the host substrate may further include an adhesion layer, e.g., iridium.

In some embodiments, step 440 may include at least one of direct wafer bonding, indium bonding, or thermocompression bonding. Of course, other appropriate bonding methods may be used, and bonding methods may be used in any appropriate combination. By way of further example, step 440 may include depositing one or more metal layers on the host substrate and bonding the host substrate, at least in part, using cold-welding. For example, depositing one or more metal layers on the host substrate may include, at least in part, depositing using e-beam evaporation

As further depicted in FIG. 4, method 400 may further include step 450, releasing the host substrate. For example, the host substrate may be released from the wafer layer.

In some embodiments, releasing the host substrate may include submerging the wafer layer in an acid, such as dilute hydrofluoric acid. Submerging the wafer layer may selectively remove the one or more sacrificial layers. For example, the wafer layer may be submerged between two and twenty-four hours. The duration of the submerging may depend on the size of the wafer layer and/or the size of the host substrate. Advantageously, submerging the compound substrate may cause dissolution of the one or more sacrificial layers, thereby detaching the active device region and host substrate from the wafer layer.

The example method 400 may include additional steps not depicted in FIG. 4. For example, method 400 may further include selectively removing the one or more protection layers. In some embodiments, selectively removing the one or more protection layers may include etching using a phosphoric acid-based etchant and etching using diluted HCl acid. Advantageously, these etchings may cause removal of the one or more protection layers from the compound substrate, thereby preparing the compound substrate for reuse.

Furthermore, localized damage to the wafer layer may be repaired according to the techniques described herein.

Any materials and layers in the embodiments disclosed above may be deposited in accordance with any techniques known in the art.

The foregoing description has been presented for purposes of illustration. It is not exhaustive and is not limited to precise forms or embodiments disclosed. Modifications and adaptations of the embodiments will be apparent from consideration of the specification and practice of the disclosed embodiments.

Moreover, while illustrative embodiments have been described herein, the scope includes any and all embodiments having equivalent elements, modifications, omissions, combinations (e.g., of aspects across various embodiments), adaptations and/or alterations based on the present disclosure. The elements in the claims are to be interpreted broadly based on the language employed in the claims and not limited to examples described in the present specification or during the prosecution of the application, which examples are to be construed as nonexclusive. Further, the steps of the disclosed methods may be modified, including reordering steps and/or inserting or deleting steps.

The features and advantages of the disclosure are apparent from the detailed specification, and thus, it is intended that the appended claims cover all systems and methods falling within the true spirit and scope of the disclosure. As used herein, the indefinite articles “a” and “an” mean “one or more.” Similarly, the use of a plural term does not necessarily denote a plurality unless it is unambiguous in the given context. Words such as “and” or “or” mean “and/or” unless specifically directed otherwise. Further, since numerous modifications and variations will readily occur to those skilled in the art, it is not desired to limit the disclosure to the exact construction and operation illustrated and described, and accordingly, all suitable modifications and equivalents may be resorted to, falling within the scope of the disclosure.

Other embodiments will be apparent to those skilled in the art from consideration of the specification and practice of the embodiments disclosed herein. It is intended that the specification and examples be considered as example only, with a true scope and spirit of the disclosed embodiments being indicated by the following claims.

What is claimed:

1. A compound substrate for use in epitaxial lift-off of a device having an expected size, comprising:
a diced wafer layer formed of a plurality of wafer pieces, wherein the wafer layer has a bottom surface and a top surface; and
a wafer-receiving layer having a surface, wherein the bottom surface of the wafer layer is attached to the surface of the wafer-receiving layer.

2. The compound substrate of claim 1, wherein the wafer-receiving layer comprises at least one semiconductor.

3. The compound substrate of claim 2, wherein the wafer-receiving layer comprises silicon.

4. The compound substrate of claim 1, wherein the wafer-receiving layer comprises at least one crystalline solid.

5. The compound substrate of claim 4, wherein the wafer-receiving layer comprises quartz.

6. The compound substrate of claim 1, wherein the wafer layer comprises at least one III-V semiconductor.

7. The compound substrate of claim 6, wherein the at least one III-V semiconductor comprises GaAs.

8. The compound substrate of claim 1, wherein the size of each wafer piece is smaller than the expected size of the device.

9. The compound substrate of claim 1, wherein the size of each wafer piece is larger than the expected size of the device.

10. The compound substrate of claim 1, wherein the plurality of wafer pieces are uniformly sized.

11. The compound substrate of claim 1, further comprising:
an active device region,
wherein the active device region is disposed on the wafer layer.

12. The compound substrate of claim 11, further comprising:
one or more sacrificial layers,
wherein the one or more sacrificial layers are disposed between the wafer layer and the active device region.

13. The compound substrate of claim 12, wherein the one or more sacrificial layers comprise at least one III-V semiconductor.

14. The compound substrate of claim 13, wherein the at least one III-V semiconductor comprises AlAs.

15. The compound substrate of claim 12, further comprising:
one or more protection layers,
wherein the one or more protection layers are disposed between the wafer layer and the one or more sacrificial layers.

16. The compound substrate of claim 15, wherein the one or more protection layers comprise at least one III-V semiconductor.

17. The compound substrate of claim 16, wherein the at least one III-V semiconductor comprises at least one of GaAs or InGaP.

18. The compound substrate of claim 15, further comprising:
a host substrate,
wherein the host substrate is bonded to the active device region.

19. The compound substrate of claim 18, wherein the host substrate comprises a Kapton sheet.

20. The compound substrate of claim 18, further comprising:
one or more metal layers,
wherein the metal layers are disposed between the active device region and the host substrate.

21. The compound substrate of claim 20, wherein the one or more metal layers comprise at least one of palladium, germanium, or gold.

22. The compound substrate of claim 15, further comprising:
a handle layer,
wherein the handle layer is attached to the active device region.

23. A method of manufacturing a compound substrate for use in epitaxial lift-off of a device having an expected size, comprising:
providing a wafer layer, wherein the wafer layer has a bottom surface and a top surface;
dicing the wafer layer into a plurality of wafer pieces; and
attaching the bottom surface of the diced wafer layer to a wafer-receiving layer.

24. The method of claim 23, further comprising depositing one or more sacrificial layers on the wafer layer after dicing.

25. The method of claim 23, wherein providing a wafer layer further comprises depositing one or more sacrificial layers on the wafer layer.

26. The method of claim 24, further comprising:
depositing an active device region after dicing,
wherein the active device region is disposed over the one or more sacrificial layers.

27. The method of claim 25, wherein:
providing a wafer layer further comprises depositing an active device region, and
the active device region is disposed over the one or more sacrificial layers.

28. The method of claim 26, further comprising:
depositing one or more protection layers after dicing,
wherein the one or more protection layers are disposed between the wafer layer and the one or more sacrificial layers.

29. The method of claim 27, wherein:
providing a wafer layer further comprises depositing one or more protection layers and,
the one or more protection layers are disposed between the wafer layer and the one or more sacrificial layers.

30. The method of claim 23, wherein attaching the bottom surface of the wafer layer to a wafer-receiving layer comprises at least one of direct wafer bonding, indium bonding, cold-welding, or using silicon on glass (SOG).

31. The method of claim 23, wherein attaching the bottom surface of the wafer layer to a wafer-receiving layer comprises, at least in part, attaching with one or more adhesives.

32. The method of claim 23, wherein dicing the wafer layer into a plurality of wafer pieces comprises dicing the wafer layer into two or more pieces individually smaller than the expected size of the device.

33. The method of claim 23, wherein dicing the wafer layer into a plurality of wafer pieces comprises dicing the wafer layer into two or more pieces individually larger than the expected size of the device.

34. The method of claim 23, wherein dicing the wafer layer into a plurality of wafer pieces comprises dicing the wafer layer into two or more pieces of uniform size.

35. The method of claim 26 or 27, further comprising bonding a host substrate to the active device region.

36. The method of claim 35, wherein the host substrate is bonded to the active device region by cold-welding.

37. A method of manufacturing a device having an expected size using epitaxial lift-off, comprising:
providing a wafer layer, wherein the wafer layer has a bottom surface and a top surface;
dicing the wafer layer into a plurality of wafer pieces;
attaching the bottom surface of the diced wafer layer to a wafer-receiving layer;
bonding a host substrate atop the wafer layer; and
releasing the host substrate from the wafer layer.

38. The method of claim 37, further comprising depositing one or more sacrificial layers on the wafer layer after dicing.

39. The method of claim 37, wherein providing a wafer layer further comprises depositing one or more sacrificial layers on the wafer layer.

40. The method of claim 38, further comprising:
depositing an active device region after dicing,
wherein the active device region is disposed over the one or more sacrificial layers.

41. The method of claim 39, wherein:
providing a wafer layer further comprises depositing an active device region, and
the active device region is disposed over the one or more sacrificial layers.

42. The method of claim 40, further comprising:
depositing one or more protection layers after dicing,
wherein the one or more protection layers are disposed between the wafer layer and the one or more sacrificial layers.

43. The method of claim 41, wherein:
providing a wafer layer further comprises depositing one or more protection layers and,
the one or more protection layers are disposed between the wafer layer and the one or more sacrificial layers.

44. The method of claim 37, wherein attaching the bottom surface of the wafer layer to a wafer-receiving layer comprises at least one of direct wafer bonding, indium bonding, cold-welding, or using silicon on glass (SOG).

45. The method of claim 37, wherein attaching the bottom surface of the wafer layer to a wafer-receiving layer comprises, at least in part, attaching with one or more adhesives.

46. The method of claim 37, wherein the host substrate is bonded by cold-welding.

47. The method of claim 37, wherein releasing the host substrate comprises submerging the wafer layer in an acid.

48. The method of claim 40 or 41, wherein releasing the host substrate comprises selectively removing the one or more sacrificial layers.

49. The method of claim 42 or 43, further comprising selectively removing the one or more protection layers after the releasing step.

50. A method of repairing a compound substrate comprising a wafer-receiving layer and a plurality of wafer pieces bonded to the wafer-receiving layer having damage in a localized area, comprising:
selectively heating the localized area;
removing the one or more pieces in the localized area, thereby forming one or more empty areas; and
bonding one or more new pieces of wafer to the wafer-receiving layer to fill the one or more empty areas.

51. The method of claim 50, wherein bonding one or more new pieces comprises at least one of direct wafer bonding, indium bonding, cold-welding, using silicon on glass (SOG), or thermocompression bonding.
